(19) United States
(12) Patent Application Publication
(10) Pub. No.: US 2013/0320522 A1
(43) Pub. Date: Dec. 5, 2013

(54) Re-distribution Layer Via Structure and Method of Making Same

(71) Applicants: Feng-Liang Lai, Tainan City (TW); Kai-Yuan Yang, Ping-Tung City (TW); Chia-Jen Leu, Tainan City (TW); Sheng Chiang Hung, Hsin-Chu (TW)

(72) Inventors: Feng-Liang Lai, Tainan City (TW); Kai-Yuan Yang, Ping-Tung City (TW); Chia-Jen Leu, Tainan City (TW); Sheng Chiang Hung, Hsin-Chu (TW)

(73) Assignee: TAIWAN SEMICONDUCTOR MANUFACTURING COMPANY, LTD., Hsin-Chu (TW)

(21) Appl. No.: 13/483,999

(22) Filed: May 30, 2012

(51) Int. Cl. H01L 23/498; H01L 21/768; H01L 23/48

(52) U.S. Cl. 257/737; 257/774; 438/613; 257/E23.01; 257/E23.068; 257/E21.585

(57) ABSTRACT

An embodiment is a semiconductor device comprising a contact pad over a substrate, wherein the contact pad is disposed over an integrated circuit on the substrate and a first passivation layer over the contact pad. A first via in the first passivation layer, wherein the first via has more than four sides, and wherein the first via extends to the contact pad.

### BACKGROUND

Generally, a semiconductor die may be connected to other devices external to the semiconductor die through different types of packaging including wire bonding or flip chip packaging utilizing solder bumps. The semiconductor die may have metallization layers comprising metal layers, dielectric layers, metal vias, re-distribution layers, and post-passivation interconnects. The wire bonding may connect integrated circuits (ICs) to substrates directly via the wiring, while the flip chip packaging (or wafer-level chip scale package (WLCSP)) solder bumps may be formed by initially forming a layer of underbump metallization on the semiconductor die and then placing solder onto the underbump metallization. After the solder has been placed, a reflow operation may be performed in order to shape the solder into the desired bump shape. The solder bump may then be placed into physical contact with the external device and another reflow operation may be performed in order to bond the solder bump with the external device. In the above two types of packaging, wire bonding and flip chip, a physical and electrical connection may be made between the semiconductor die and an external device, such as a printed circuit board, another semiconductor die, or the like.

### BRIEF DESCRIPTION OF THE DRAWINGS

For a more complete understanding of the present embodiments, and the advantages thereof, reference is now made to the following descriptions taken in conjunction with the accompanying drawings, in which:

FIG. 1a illustrates a cross-sectional view of a semiconductor device according to an embodiment;

FIG. 1b illustrates a cross-sectional view of a semiconductor device according to another embodiment;

FIG. 1c illustrates a cross-sectional view of a semiconductor device according to yet another embodiment;

FIGS. 2a through 2g illustrate top-down views of via openings according to embodiments;

FIGS. 3 through 10 illustrate the formation of a semiconductor device according to an embodiment; and

FIGS. 11a and 11b illustrate the results of testing a semiconductor device according to an embodiment.

### DETAILED DESCRIPTION OF ILLUSTRATIVE EMBODIMENTS

Reference will now be made in detail to embodiments illustrated in the accompanying drawings. Wherever possible, the same reference numbers are used in the drawings and the description to refer to the same or like parts. In the drawings, the shape and thickness may be exaggerated for clarity and convenience. This description will be directed in particular to elements forming part of, or cooperating more directly with, methods and apparatus in accordance with the present disclosure. It is to be understood that elements not specifically shown or described may take various forms well known to those skilled in the art. Many alternatives and modifications will be apparent to those skilled in the art, once informed by the present disclosure.

Reference throughout this specification to “one embodiment” or “an embodiment” means that a particular feature, structure, or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments. It should be appreciated that the following figures are not drawn to scale; rather, these figures are merely intended for illustration.

Embodiments will be described with respect to a specific context, namely a redistribution layer via over a metal feature. Other embodiments may also be applied, however, to post-passivation interconnects or other vias over a metal feature.

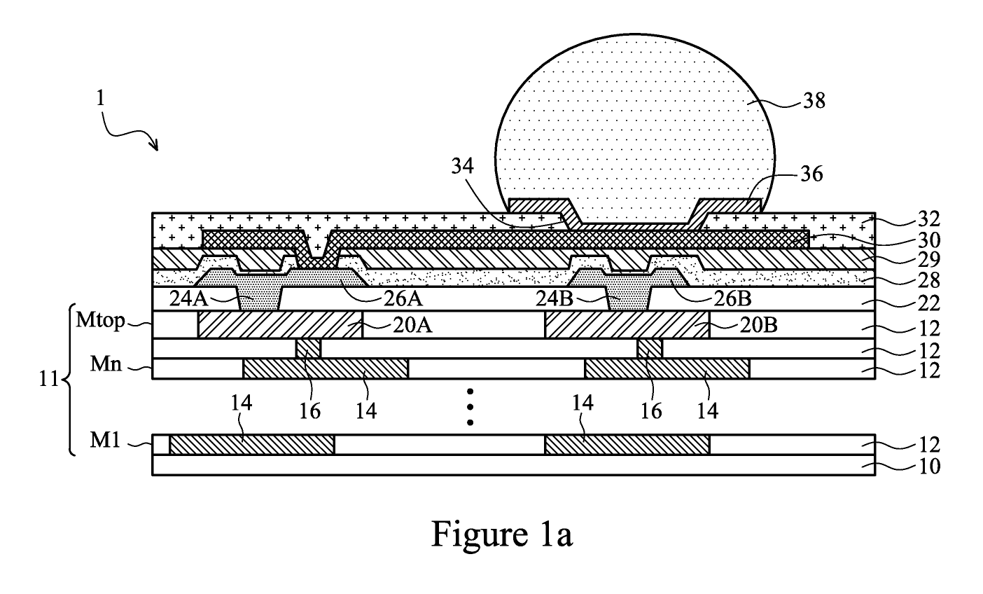

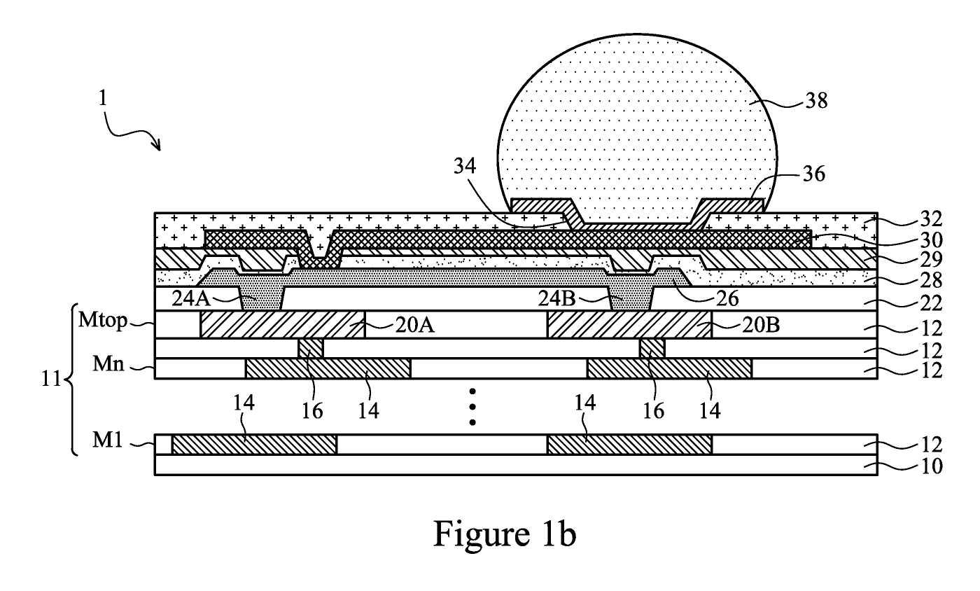

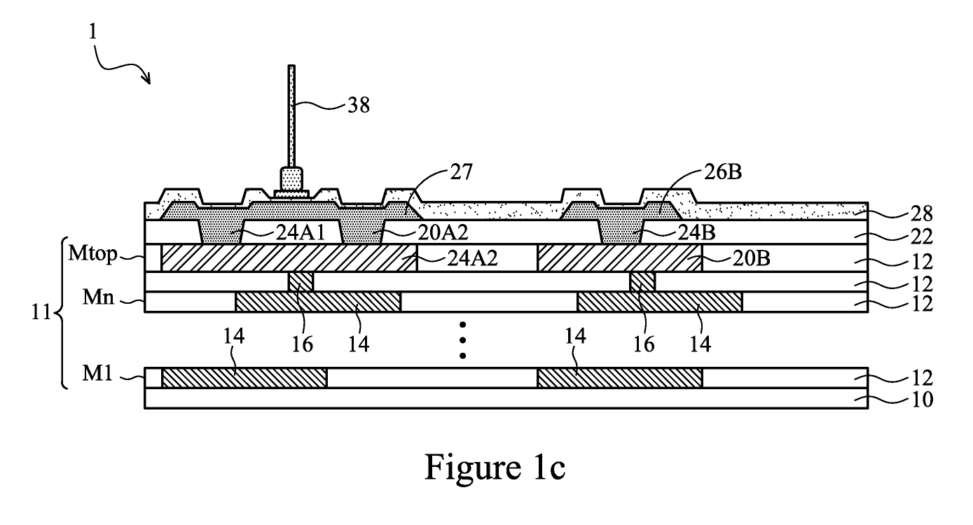

With reference now to FIG. 1a, there is shown a portion of a semiconductor die 1 including a substrate 10 with an interconnect structure 11, a first contact pad 20A, a second contact pad 20B, a first passivation layer 22, a first redistribution layer (RDL) via opening 24A through the first passivation layer 22, a second RDL via opening 24B through the first passivation layer 22, a first RDL 26A, a second RDL 26B, a second passivation layer 28 and a third passivation layer 29 over the first and second RDLs 26A and 26B, a third RDL 30, a fourth passivation layer 32 over the third RDL 30, an underbump metallization (UBM) opening 34, an UBM 36, and a connector 38. In this embodiment, the substrate 10 may be silicon and, in other embodiments, includes silicon germanium (SiGe), silicon oxide, nitride, the like, or a combination thereof. The substrate 10 may include integrated circuits comprising active and passive devices.

The interconnect structure 11 comprises metal lines 14 and vias 16 to electrically connect the various active and passive devices to form functional circuitry. Conductive materials, such as copper, aluminum, or the like, with or without a barrier layer, can be used as the metal lines 14 and the vias 16. The metal lines 14 and the vias 16 may be formed using a single and/or a dual damascene process, a via-first process, or a metal-first process. Interconnect structure 11 includes a plurality of metal layers, namely M1, Mn . . . Mtop, wherein metal layer M1 is the metal layer immediately above the substrate 10, while metal layer Mn is an intermediate layer above metal layer M1, and metal layer Mtop is the top metal layer that is immediately under the overlying RDL 26. Throughout the description, the term “metal layer” refers to the collection of the metal lines in the same layer. Metal layers M1 through Mn through Mtop are formed in inter-metal dielectrics (IMDs) 12, which may be formed of oxides such as silicon oxide, borophosphosilicate glass (BPSG), undoped silicate glass (USG), fluorinated silicate glass (FSG), low-k dielectric materials, the like, or a combination thereof. The low-k dielectric materials may have k values lower than 3.9.

The metal layer Mtop may comprise one or more contact pads such as first contact pad 20A and a second contact pad 20B. The first and second contact pads 20A and 20B may be formed over and in electrical contact with the metal layers Mn of the interconnect structure 11. The first and second contact pads 20A and 20B may comprise copper, aluminum, aluminum copper, tungsten, nickel, the like, or a combination thereof. In an embodiment, the metal lines 14 and first and second contact pads 20A and 20B may be formed to a thickness from about 0.3 um to about 1.2 um. In another embodiment, the metal layer Mtop and the first and second contact pads 20A and 20B may be a top metal or an ultra-thick metal (UTM) formed to a thickness of about 3 times the thickness a typical top metal or about 10 times the thickness of the other metal layers Mn through M1. It is realized, however, that the dimensions recited throughout the description are merely examples, and may be changed in alternative embodiments.

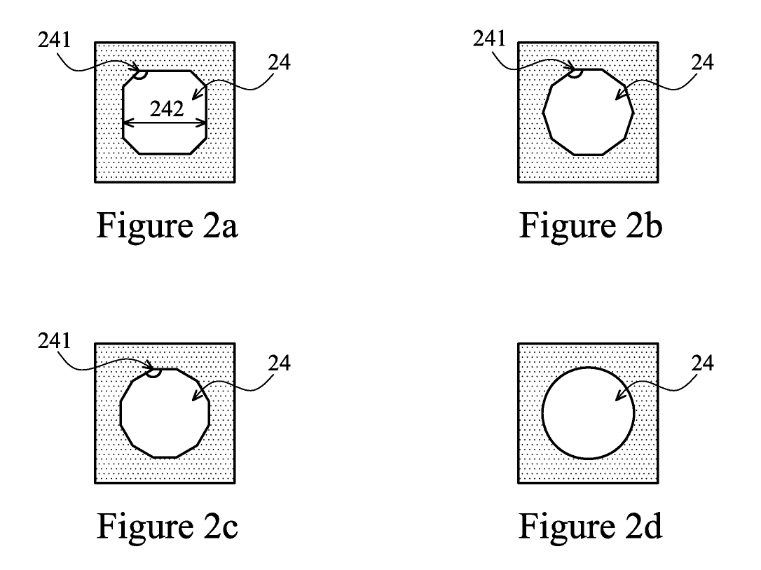

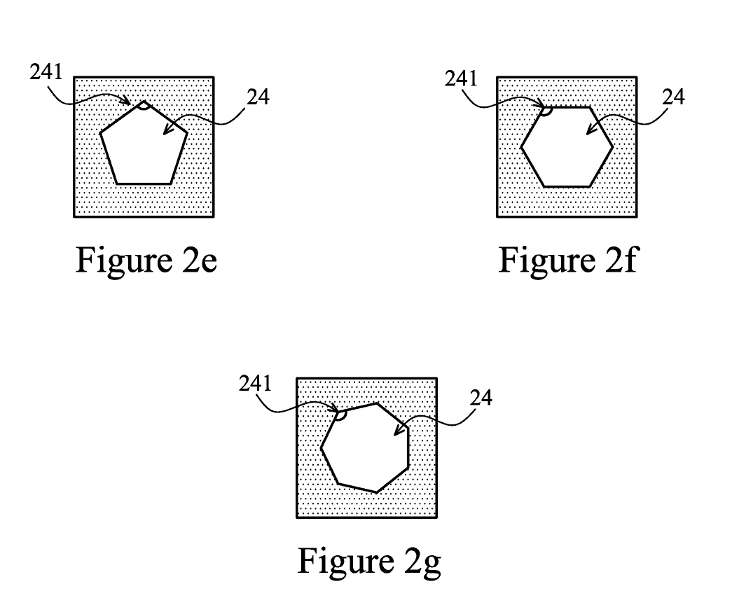

The first passivation layer 22 may be formed over the interconnect structure 11 and the first and second contact pads 20A and 20B. In an embodiment, the first passivation layer 22 may be formed to a thickness between about 0.7 um and about 1 um. After the first passivation layer 22 has been formed, one or more RDL via openings, such as a first RDL via opening 24A and a second RDL via opening 24B, may be made through the first passivation layer 22 by removing portions of the first passivation layer 22 to expose at least a portion of the underlying first and second contact pads 20A and 20B. The first RDL via opening 24A allows for contact between the first contact pad 20A and the first RDL 26A (discussed further below). The second RDL via opening 24B allows for contact between the second contact pad 20B and the second RDL 26B (discussed further below). The first and second RDL via openings 24A and 24B may be formed using a suitable photolithographic mask and etching process, although any suitable process to expose portions of the first and second contact pads 20A and 20B may be used. In an embodiment, the diameter 242 of one of the RDL via openings 24 may be between about 1.5 um and about 5 um (see FIG. 2a).

The RDL via openings 24 may have more than four sides when viewed from the top with an internal angle 241, the angle between adjoining sides of the RDL via openings 24, of greater than about 90° (see FIGS. 2a through 2g). As shown in FIG. 2a, the RDL via openings 24 may have eight sides forming an octagon with eight internal angles 241 of about 135°. In an embodiment, the sides of the RDL via openings 24 are not the same length, such as in FIG. 2a wherein the RDL via openings 24 comprises four long sides and four short sides alternating around the perimeter of the RDL via openings 24. The four long sides are substantially the same length as each other and the four short sides are substantially the same length as each other. In another embodiment, the sides of the RDL via openings 24 may be the same length.

FIGS. 2b through 2g illustrate other embodiments of the RDL via openings 24. FIG. 2b illustrates a RDL via opening 24 with ten sides forming a decagon with ten internal angles 241 of about 144°. FIG. 2c illustrates a RDL via opening 24 with twelve sides forming a dodecagon with twelve internal angles 241 of about 150°. FIG. 2d illustrates a RDL via opening 24 forming a circle. In another embodiment, the RDL via opening 24 could have many sides, e.g., more than thirty sides, to substantially form a circle. FIG. 2e illustrates a RDL via opening 24 with five sides forming a pentagon with five internal angles 241 of about 108°. FIG. 2f illustrates a RDL via opening 24 with six sides forming a hexagon with six internal angles 241 of about 120°. FIG. 2g illustrates a RDL via opening 24 with seven sides forming a heptagon with seven internal angles 241 of about 128.6°. As one of ordinary skill in the art will appreciate, the RDL via opening 24 may be formed to be a polygon having any number of sides and internal angles, not just the illustrative embodiments of FIG. 2. In addition, FIG. 2b through 2g may also include sides of varying lengths as discussed above in reference to FIG. 2a.

Returning to FIG. 1a, after the first and second RDL via openings 24A and 24B have been formed, the first and second RDLs 26A and 26B may be formed to extend along the first passivation layer 22 and may be in electrical connection with the first and second contact pads 20A and 20B. The first and second RDLs 26A and 26B may be utilized to provide electrical connection between the first and second contact pads 20A and 20B and the third RDL 30 and other metal features in layers above the first and second RDLs 26A and 26B. In an embodiment, the first and second RDLs 26A and 26B may comprise aluminum, copper, an aluminum copper alloy, the like, or a combination thereof and may be formed to have a thickness between about 1.4 um and about 2.8 um. In some embodiments, one or more barrier layers (not shown) may be formed in the first and second RDL via openings 24A and 24B comprising titanium, titanium nitride, tantalum, tantalum nitride, the like, or a combination thereof.

After the formation of the first and second RDLs 26A and 26B, the second passivation layer 28 and the third passivation layer 29 may be formed to protect and electrically isolate the first and second RDLs 26A and 26B and other underlying structures. In an embodiment, the second passivation layer 28 is conformal and has substantially the same thickness across the semiconductor die 1. The second passivation layer 28 may comprise USG, FSG, SiOₓ, SiN, the like, or a combination thereof. The third passivation layer 29 may comprise silicon nitride, silicon oxide, a polymer, the like, or a combination thereof. In an embodiment, the second passivation layer 28 may be formed to have a thickness between about 1 um and about 2 um, and the third passivation layer 29 may be formed to have a thickness of about 5 um.

After the third passivation layer 29 has been formed, a third RDL 30 may be formed along the third passivation layer 29 and may be in electrical connection with the first RDL 26A. The third RDL 30 may be utilized to provide electrical connection between the first RDL 26A and the UBM 36 and the connector 38. In an embodiment, the third RDL 30 may comprise copper, aluminum, an aluminum copper alloy, or the like.

After the third RDL 30 has been formed, a fourth passivation layer 32 may be formed to protect and electrically isolate the third RDL 30 and other underlying structures. In an embodiment, the fourth passivation layer 32 may comprise silicon nitride, silicon oxide, a polymer, the like, or a combination thereof formed to a thickness of about 5 um.

After the fourth passivation layer 32 has been formed, an UBM opening 34 may be made through the fourth passivation layer 32 followed by the formation of UBM 36. After the UBM 36 has been formed, a connector 38 may be formed over the UBM 36.

In FIG. 1b, another embodiment of a semiconductor die 1 is illustrated. In this embodiment, the first and second RDLs 26A and 26B from FIG. 1a are electrically and physically connected to form a single RDL 26. The RDL 26 is in electrical connection with the first and second contact pads 20A and 20B. The formation of the semiconductor die 1 is similar to the previous embodiment.

FIG. 1c illustrates yet another embodiment of a semiconductor die 1. In this embodiment the fourth RDL 27 is electrically connected to the first contact pad 20A by two RDL via openings 24A1 and 24A2 rather than a single opening (see FIGS. 1a and 1b). Also in this embodiment, the connector 38 comprises a wire bond rather than a solder bump (see FIGS. 1a and 1b). The formation of the semiconductor die 1 is similar to the previous embodiments.

Although the previous embodiments illustrate specific configurations of the contact pads, the RDL via openings, and the RDLs, other embodiment may contemplate other configurations with more or less contact pads, RDL via openings, or RDLs.

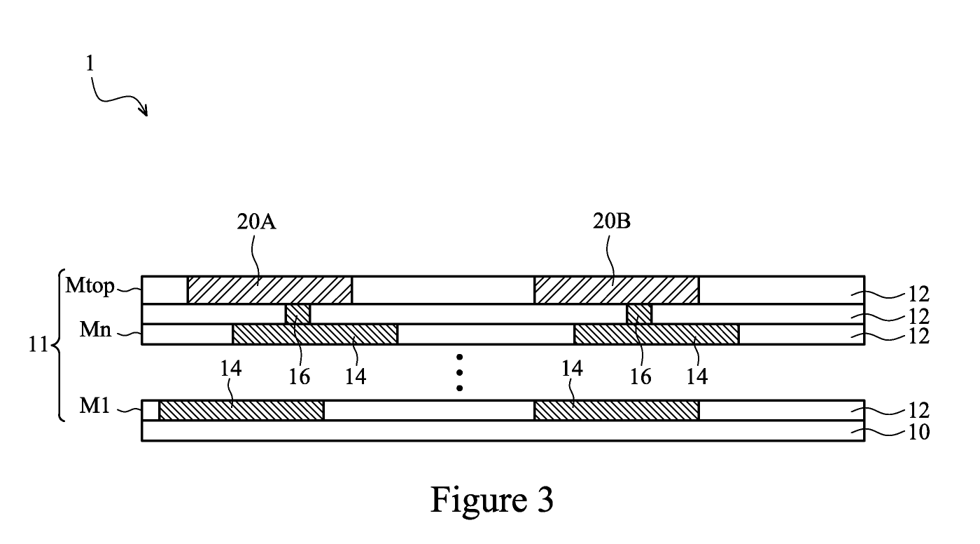

FIGS. 3 through 10 illustrate a process to form a semiconductor die 1 according to an embodiment. Although this embodiment is discussed with steps performed in a particular order, steps may be performed in any logical order.

FIG. 3 illustrates a substrate 10 and metal layers M1 through Mtop at an intermediate stage of processing. The substrate 10 may be silicon, SiGe, silicon carbide, the like, or a combination thereof. The substrate 10 may comprise bulk silicon, doped or undoped, or an active layer of a silicon-on-insulator (SOI) substrate. Other substrates that may be used include multi-layered substrates, gradient substrates, or hybrid orientation substrates.

The substrate 10 may include integrated circuits comprising active and passive devices (not shown). As one of ordinary skill in the art will recognize, a wide variety of active and passive devices such as transistors, capacitors, resistors, combinations of these, or the like may be used to generate the structural and functional requirements of the design for the semiconductor die 1. The integrated circuits comprising active and passive devices may be formed using any suitable methods.

As shown in FIG. 3, the IMDs 12 and metal lines 14 and vias 16 are formed over the substrate 10. In an embodiment, the metal lines 14 and vias 16 may be coupled to the integrated circuits on the substrate 10 to allow other devices to be coupled to the integrated circuits. Each of the IMDs 12 can be silicon oxide, BPSG, PSG, FSG, the like, or a combination thereof, formed by chemical vapor deposition (CVD), high-density plasma CVD (HDP-CVD), furnace deposition, plasma-enhanced CVD (PECVD), the like, or a combination thereof. The metal lines 14 and vias 16 in each of the IMDs 12 can be formed using, for example, a damascene process like a dual damascene and may comprise aluminum, or copper aluminum alloys, the like, or a combination thereof. The metal lines 14 and the vias 16 may be deposited using, for example, CVD, atomic layer deposition (ALD), physical vapor deposition (PVD), the like, or a combination thereof. A polishing and/or grinding process, such as a chemical mechanical polish (CMP), can remove excess conductive materials. The IMDs 12 are sequentially formed, along with the respective vias 16 and metal lines 14.

The first and second contact pads 20A and 20B may be formed over the metal lines 14 and vias 16. The first and second contact pads 20A and 20B may comprise copper, aluminum, aluminum copper, tungsten, nickel, the like, or a combination thereof and may be formed by a similar process as the metal lines 14 as described above. In another embodiment, the first and second contact pads 20A and 20B may be formed and patterned before the formation of the top IMD 12. The first and second contact pads 20A and 20B may be an UTM formed to a thickness of about 3 times the thickness of a typical top metal or about 10 times the thickness of the other metal layers Mn and M1. In another embodiment, the first and second contact pads 20A and 20B may be a similar thickness to the other metal layers Mn through M1. It should be noted that many other components may be included in an embodiment that are not expressly depicted. For example, etch stop layers can be disposed between the various interfaces between layers of the substrate 10 and IMDs 12. Further, more or fewer IMDs 12 and metal layers can be used.

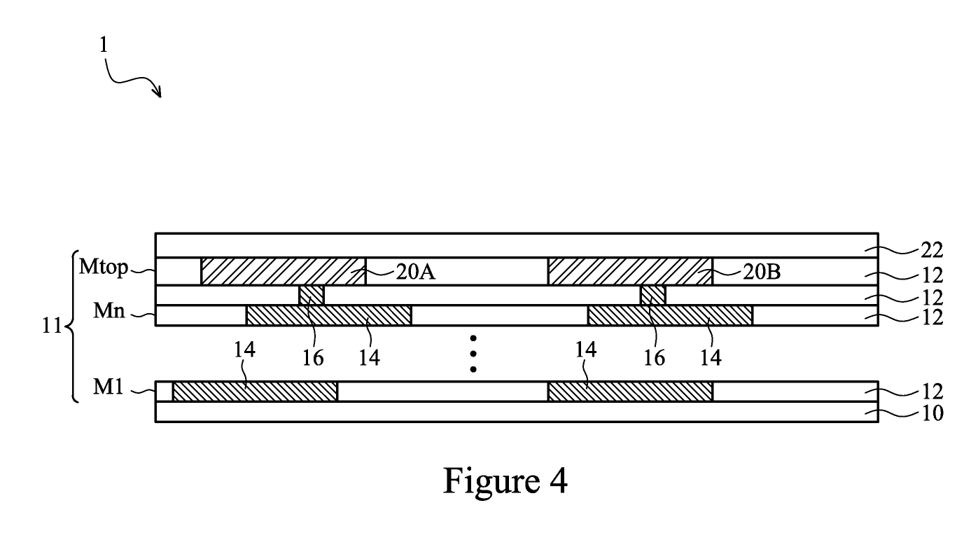

In FIG. 4, the formation of the first passivation layer is illustrated. The first passivation layer 22 is formed over first and second contact pads 20A and 20B and the top IMD 12. The first passivation layer 22 can be silicon nitride, silicon carbide, silicon oxide, low-k dielectrics such as carbon doped oxides, extremely low-k dielectrics such as porous carbon doped silicon dioxide, the like, or a combination thereof, and deposited by CVD or the like.

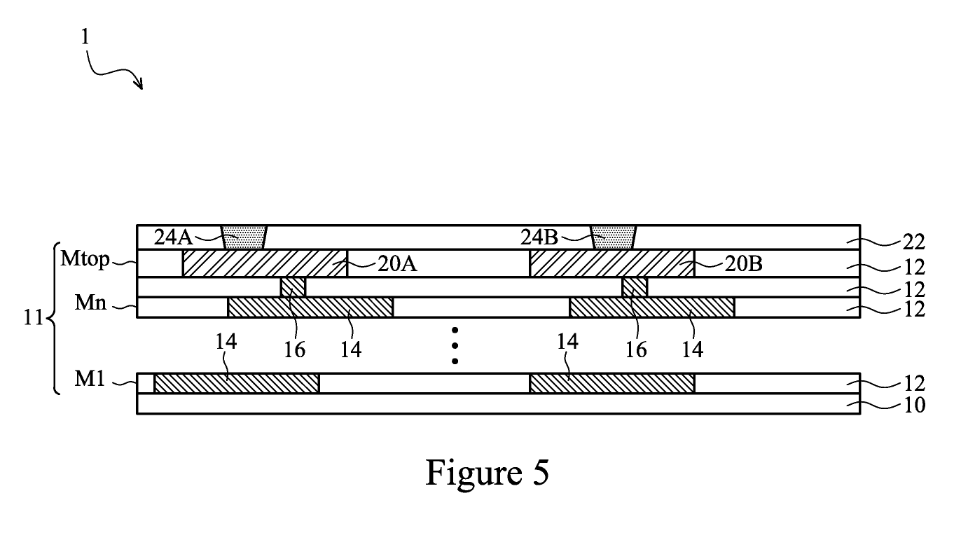

FIG. 5 illustrates the formation of the first and second RDL via openings 24A and 24B in the first passivation layer 22. The first and second RDL via openings 24A and 24B may be made through the first passivation layer 22 by removing portions of the first passivation layer 22 to expose at least a portion of the underlying first and second contact pads 20A and 20B. The first and second RDL via openings 24A and 24B allows for contact between the first and second contact pads 20A and 20B and the subsequently formed first and second RDLs 26A and 26B. The first and second RDL via openings 24A and 24B may be formed using a suitable photolithographic mask and etching process, although any suitable process to expose portions of the first and second contact pads 20A and 20B may be used. As discussed above in reference to FIG. 2, the first and second RDL via openings 24A and 24B may comprise more than four sides when viewed from the top with an internal angle 241 of greater than about 90°.

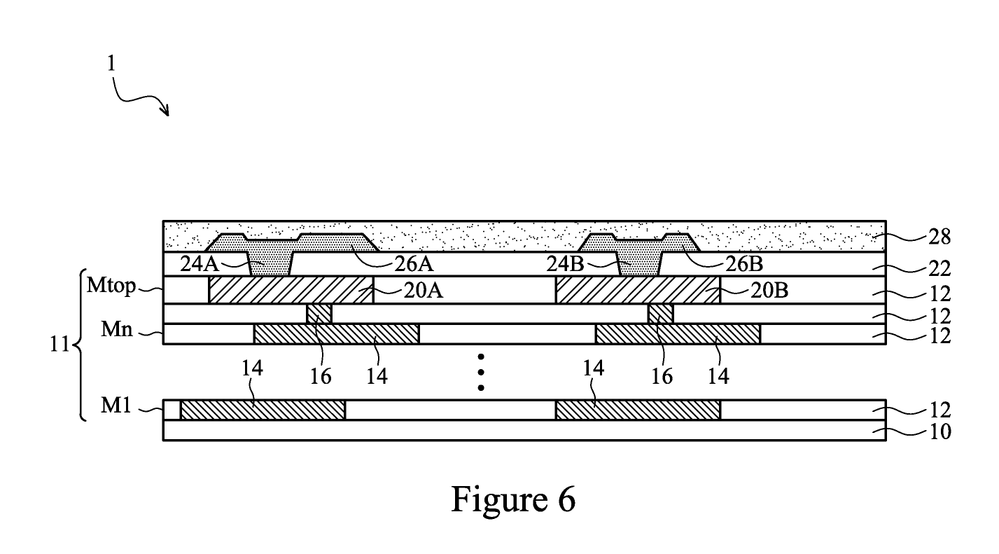

In FIG. 6, the formation of the first and second RDLs 26A and 26B is illustrated. The first and second RDLs 26A and 26B may be formed to extend along the first passivation layer 22 and into the first and second RDL via openings 24A and 24B, respectively. In some embodiments, one or more barrier layers (not shown) may be formed in the first and second RDL via openings 24A and 24B comprising titanium, titanium nitride, tantalum, tantalum nitride, the like, or a combination thereof. The one or more barrier layers may be formed along the first passivation layer 22 and in the first and second RDL via openings 24A and 24B by CVD, PVD, PECVD, ALD, the like, or a combination thereof. In an embodiment the first and second RDLs 26A and 26B may be formed by forming a seed layer (not shown) of a titanium copper alloy on the one or more barrier layers, if present, through CVD, sputtering, the like, or a combination thereof. A photoresist (not shown) may then be formed to cover the seed layer, and the photoresist may then be patterned to expose those portions of the seed layer that are located where the first and second RDLs 26A and 26B are desired to be located. Once the photoresist has been formed and patterned, a conductive material, such as copper, aluminum, aluminum copper, gold, the like or a combination thereof may be formed on the seed layer through a deposition process such as plating, CVD, PVD, the like, or a combination thereof. Once the conductive material has been formed, the photoresist may be removed through a suitable removal process such as ashing. Additionally, after the removal of the photoresist, those portions of the seed layer that were covered by the photoresist may be removed through, for example, a suitable etch process using the conductive material as a mask.

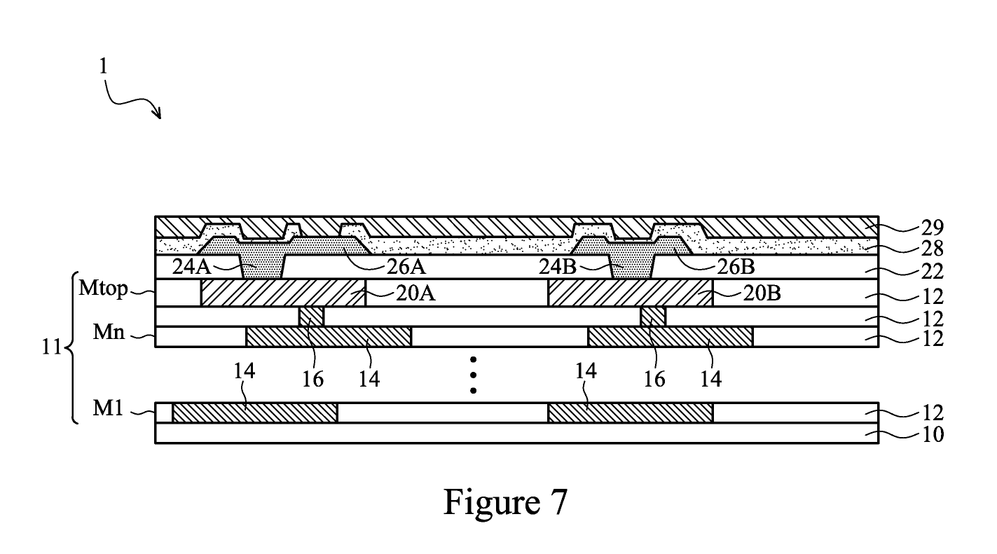

FIG. 7 illustrates the formation of the second passivation layer 28 and the third passivation layer 29 to protect and electrically isolate the first and second RDLs 26A and 26B and other underlying structures. The second passivation layer 28 may comprise USG, FSG, SiOₓ, SiN, the like, or a combination thereof and may be conformally deposited, by CVD or the like, over the first RDL 26A, the second RDL 26B, and the first passivation layer 22 to have the substantially same thickness across the semiconductor die 1. The third passivation layer 29 may comprise silicon nitride, silicon oxide, a polymer, the like, or a combination thereof, and may be deposited by CVD or the like. Although two passivation layers are shown over the first and second RDLs 26A and 26B, in other embodiments only one passivation layer may be over the first and second RDLs 26A and 26B.

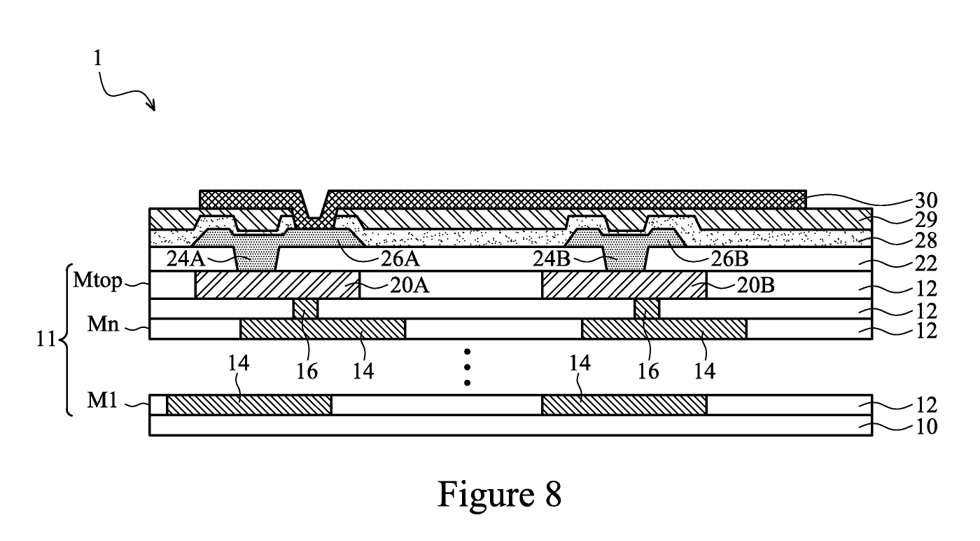

In FIG. 8, the formation of the third RDL 30 is illustrated. After the formation of the third passivation layer 29, a via may be formed through the second passivation layer 28 and the third passivation layer 29 to expose a portion of the first RDL 26A. The third RDL 30 may be formed to extend along the third passivation layer 29 and into the via. The third RDL 30 may be utilized to allow the subsequently formed UBM 36 that is electrically connected to the first contact pad 20A to be placed in any desired location on the semiconductor die 1, instead of limiting the location of the UBM 36 to the region directly over the first contact pad 20A. In an embodiment, the third RDL 30 may be formed by initially forming a seed layer (not shown) of a titanium copper alloy through CVD, sputtering, the like, or a combination thereof. A photoresist (not shown) may then be formed to cover the seed layer, and the photoresist may then be patterned to expose those portions of the seed layer that are located where the third RDL 30 is desired to be located. Once the photoresist has been formed and patterned, a conductive material, such as copper, aluminum, aluminum copper, gold, the like or a combination thereof may be formed on the seed layer through a deposition process such as plating, CVD, PVD, the like, or a combination thereof. Once the conductive material has been formed, the photoresist may be removed through a suitable removal process such as ashing. Additionally, after the removal of the photoresist, those portions of the seed layer that were covered by the photoresist may be removed through, for example, a suitable etch process using the conductive material as a mask.

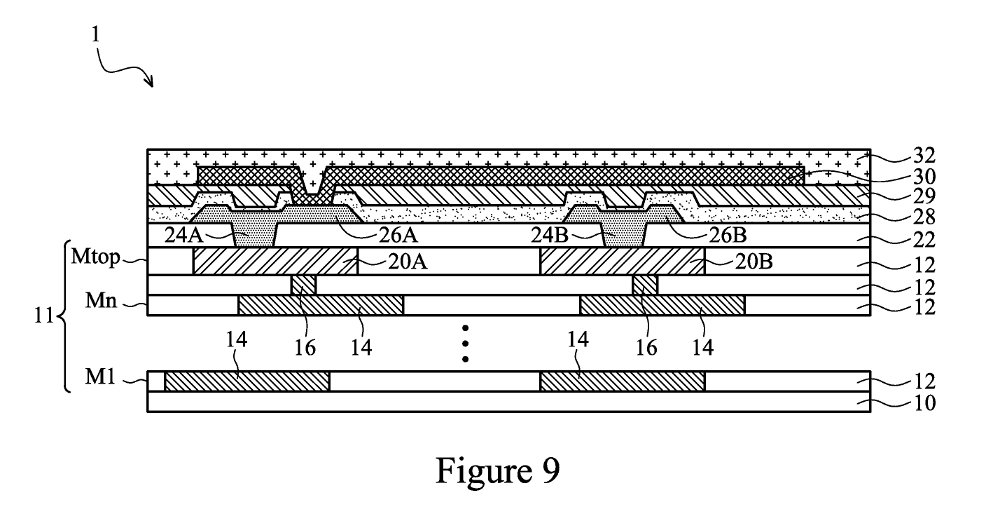

FIG. 9 illustrates the formation of the fourth passivation layer 32 to protect and electrically isolate the third RDL 30 and other underlying structures. The fourth passivation layer 32 may comprise silicon nitride, silicon oxide, a polymer, the like, or a combination thereof, and may be deposited by CVD or the like to a thickness of about 5 um. In an embodiment, the fourth passivation layer 32 is conformal and has substantially the same thickness across the semiconductor die 1. In another embodiment, the fourth passivation layer 32 may be planarized to form a substantially planar top surface.

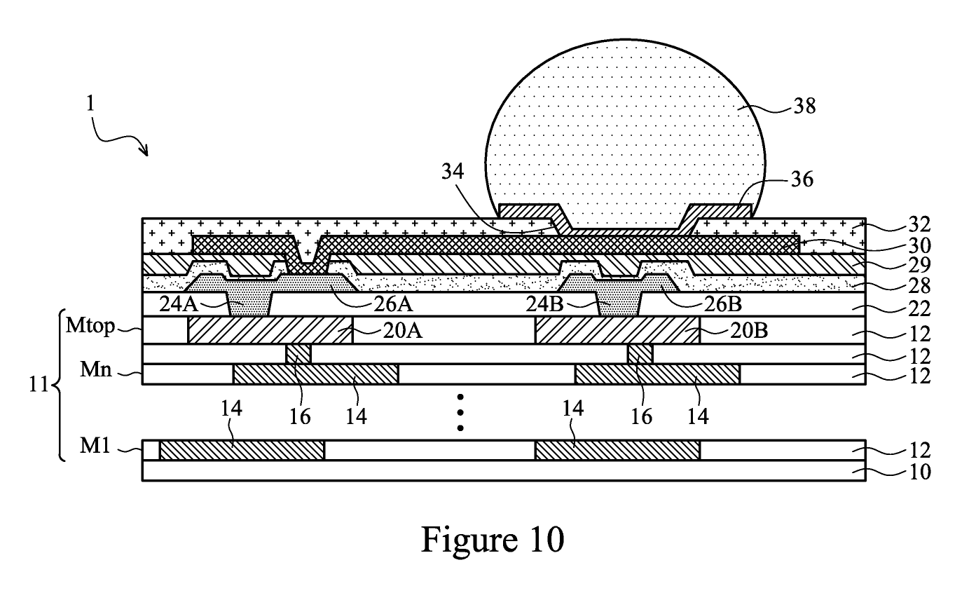

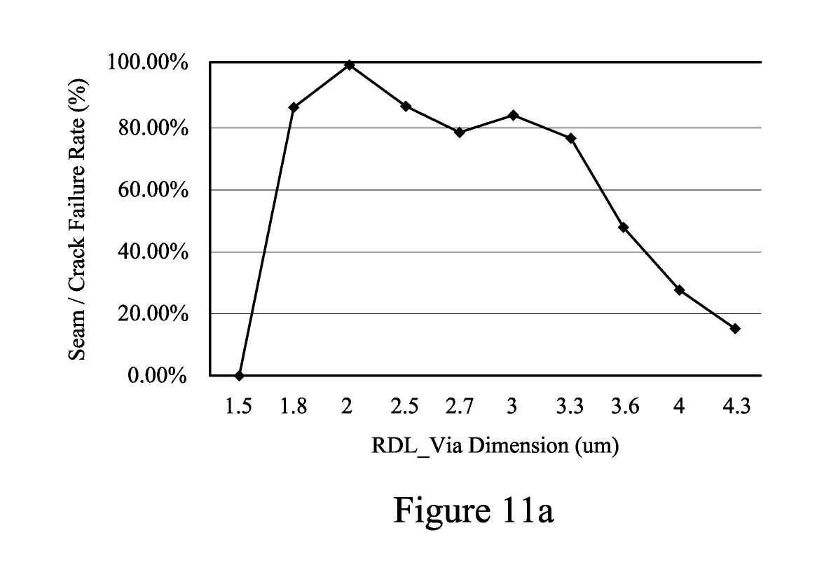

FIG. 10 illustrates the formation of the UBM 36 and the connector 38. After the fourth passivation layer 32 has been formed, an UBM opening 34 may be made through the fourth passivation layer 32 by removing portions of the fourth passivation layer 32 to expose at least a portion of the underlying third RDL 30. The UBM opening 34 allows for contact between the UBM 36 and the third RDL 30. The UBM opening 34 may be formed using a suitable photolithographic mask and etching process, although any suitable process to expose portions of the third RDL 30 may alternatively be used.

Once the third RDL 30 has been exposed through the fourth passivation layer 32, the UBM 36 may be formed in electrical contact with the third RDL 30. The UBM 36 may comprise one or more layers of conductive material. There are many suitable arrangements of materials and layers, such as an arrangement of chrome/chrome-copper alloy/copper/gold, an arrangement of titanium/titanium tungsten/copper, or an arrangement of copper/nickel/gold, that are suitable for the formation of the UBM 36. Any suitable materials or layers of material that may be used for the UBM 36 are fully intended to be included within the scope of the current application.

The connector 38 may be a contact bump, a wire bond, a metal pillar, or the like and may comprise a material such as tin, silver, lead-free tin, copper, the like, or a combination thereof. In an embodiment in which the connector 38 is a contact bump, the connector 38 may be formed by initially forming a layer of conductive material on the UBM 36. Once the layer of conductive material has been formed on the UBM 36, a reflow may be performed in order to shape the material into the desired bump shape. In another embodiment, the connector 38 may be a wire bond (see FIG. 1c) and a wire bonding is performed to form a wire bond connector that may be bonded either to the first and second RDL 26A and 26B or the third RDL 30.

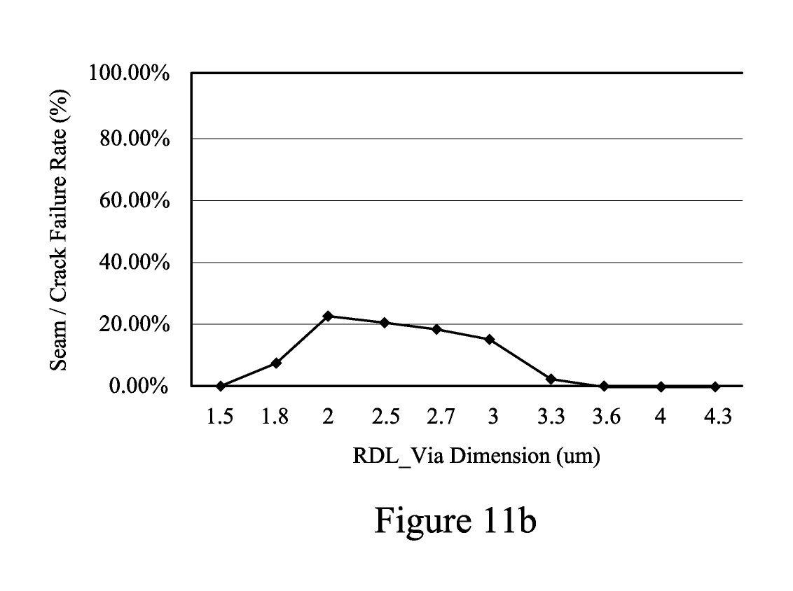

Embodiments may achieve advantages. A RDL via opening 24 with more than four sides and internal angles 241 of greater than about 90° may reduce the formation of a seam or crack in the second passivation layer 28 and the third passivation layer 29 over the RDL via opening 24. FIG. 11a illustrates the percentage of tests that have a seam or crack in the passivation layers over a RDL via opening 24 with four sides and via diameters between 1.5 um to 4.3 um. FIG. 11b illustrates the percentage of tests that have a seam or crack in the passivation layers over a RDL via opening with eight sides and internal angles of 135° and via diameters between 1.5 um to 4.3 um. As shown in FIG. 11b, the failure rate of RDL via openings 24 with eight sides and internal angles of 135° may be reduced up to 80% depending on the via size. In addition, the window of via diameters with very low to no failures is reduced to between about 1.5 um and about 3.3 um.

An embodiment is a semiconductor device comprising a contact pad over a substrate, wherein the contact pad is disposed over an integrated circuit on the substrate and a first passivation layer over the contact pad. A first via in the first passivation layer, wherein the first via has more than four sides, and wherein the first via extends to the contact pad.

Another embodiment is a semiconductor device comprising a first contact pad over a substrate, a first passivation layer over the first contact pad, a first via through the first passivation layer, wherein the first via has more than four sides, and a first RDL over the first passivation layer and the first via, wherein the first RDL contacts the first contact pad through the first via.

Yet another embodiment is a method of manufacturing a semiconductor device comprising forming an integrated circuit on a substrate, forming a contact pad over the substrate, and depositing a first passivation layer over the contact pad. A first via is formed through the first passivation layer, wherein the first via comprises more than four sides.

Although the present embodiments and their advantages have been described in detail, it should be understood that various changes, substitutions, and alterations can be made herein without departing from the spirit and scope of the disclosure as defined by the appended claims. Moreover, the scope of the present application is not intended to be limited to the particular embodiments of the process, machine, manufacture, composition of matter, means, methods, and steps described in the specification. As one of ordinary skill in the art will readily appreciate from the disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A semiconductor device comprising:
a contact pad over a substrate, wherein the contact pad is disposed over an integrated circuit on the substrate;
a first passivation layer over the contact pad; and
a first via in the first passivation layer, wherein the first via has more than four sides, and wherein the first via extends to the contact pad.

2. The semiconductor device of claim 1, wherein the first via has a diameter between about 1.5 um and about 5 um.

3. The semiconductor device of claim 1, wherein the contact pad has a thickness between about 3 um and about 12 um.

4. The semiconductor device of claim 1, wherein the first via has an internal angle of greater than about 90°.

5. The semiconductor device of claim 1, wherein the first via has an internal angle of about 135° or greater.

6. The semiconductor device of claim 1, wherein the first via has eight or more sides.

7. The semiconductor device of claim 1 further comprising:
a first metal feature on the first passivation layer and in the first via, wherein the first metal feature has substantially a same thickness on the first passivation layer and in the first via, and wherein the first metal feature is in electrical and physical contact with the contact pad;
a second passivation layer on the first metal feature, wherein the second passivation layers has substantially a same thickness on the first metal feature; and
a third passivation layer on the second passivation layer.

8. The semiconductor device of claim 7, wherein the first metal feature is a redistribution layer (RDL).

9. A semiconductor device comprising:
a first contact pad over a substrate;
a first passivation layer over the first contact pad;
a first via through the first passivation layer, wherein the first via has more than four sides; and
a first RDL over the first passivation layer and the first via, wherein the first RDL contacts the first contact pad through the first via.

10. The semiconductor device of claim 9 further comprising:
a second contact pad laterally spaced from the first contact pad, wherein the first passivation layer is over the second contact pad;
a second via through the first passivation layer, wherein the second via has more than four sides; and
a second RDL over the first passivation layer and the second via, wherein the second RDL contacts the second contact pad through the second via.

11. The semiconductor device of claim 9, wherein the via has eight or more sides and the via has an internal angle of about 135° or greater.

12. The semiconductor device of claim 11, wherein the via comprises four long sides and four short sides alternating around a perimeter of the via.

13. The semiconductor device of claim 9, wherein the sides of the via are substantially a same length.

14. The semiconductor device of claim 9 further comprising:
a second passivation layer over the first RDL;
a second via through the second passivation layer;
a second RDL over the second passivation layer and the second via, wherein the second RDL contacts the first contact pad through the second via;
a third passivation layer over the second RDL;
an opening though the third passivation layer;
a underbump metallization (UBM) extending into the opening; and
a contact bump on the UBM.

15. The semiconductor device of claim 14, wherein the second passivation layer comprises an undoped silicate glass (USG) layer contacting the RDL, and a silicon nitride layer contacting the USG layer.

16. A method of manufacturing a semiconductor device, the method comprising:
forming an integrated circuit on a substrate;
forming a contact pad over the substrate;
depositing a first passivation layer over the contact pad; and
forming a first via through the first passivation layer, wherein the first via comprises more than four sides.

17. The method of claim 16, further comprising:
before the forming the contact pad, forming an interconnect structure over the integrated circuit, wherein the contact pad is electrically coupled to the interconnect structure;
forming a first RDL over the first passivation layer, wherein the first RDL extends into the first via;
depositing a second passivation layer over the first RDL;
forming a second via through the second passivation layer;
forming a second RDL over the second passivation layer, wherein the second RDL extends into the second via;
depositing a third passivation layer over the second RDL;
forming an opening through the second passivation layer;
forming a UBM in the opening; and
forming a contact bump on the UBM.

18. The method of claim 17, wherein the depositing the second passivation layer comprises:
conformally depositing a USG layer on the RDL; and
depositing a silicon nitride layer on the USG layer.

19. The method of claim 16, wherein the via comprises eight or more sides with an internal angle of about 135° or greater.

20. The method of claim 16, wherein the via has a diameter between about 1.5 um and about 5 um.
